(19) United States
(12) Patent Application Publication
(10) Pub. No.: US 2025/0022812 A1
(43) Pub. Date: Jan. 16, 2025

(54) SEMICONDUCTOR PACKAGE

(71) Applicant: SAMSUNG ELECTRONICS CO., LTD., SUWON-SI (KR)

(72) Inventors: Hansung Ryu, SUWON-SI (KR); Jongbeom Park, SUWON-SI (KR)

(21) Appl. No.: 18/642,633

(22) Filed: Apr. 22, 2024

(30) Foreign Application Priority Data
Jul. 13, 2023 (KR) 10-2023-0091226

(51) Int. Cl. H01L 23/00; H01L 23/31; H01L 23/48; H01L 25/065; H10B 80/00

(52) U.S. Cl. CPC H01L 23/562; H01L 23/3157; H01L 23/481; H01L 24/08; H01L 25/0657; H10B 80/00; H01L 2224/08145

(57) ABSTRACT

A semiconductor package includes a first semiconductor chip that includes a first semiconductor substrate that includes an active surface and an inactive surface opposite to each other and a plurality of first through silicon vias that penetrate through the first semiconductor substrate, and a plurality of second semiconductor chips that each include a second semiconductor substrate that includes an active surface and an inactive surface opposite to each other and a plurality of second through silicon vias that penetrates through the second semiconductor substrate. Each of the plurality of second semiconductor chips is stacked on the first semiconductor chip, such that the active surface of each second semiconductor substrate faces the inactive surface of the first semiconductor substrate, and the plurality of second semiconductor chips have the same vertical height.

### CROSS-REFERENCE TO RELATED APPLICATIONS

This application claims priority under 35 U.S.C. § 119 from Korean Patent Application No. 10-2023-0091226, filed on Jul. 13, 2023 in the Korean Intellectual Property Office, the contents of which are herein incorporated by reference in their entirety.

### TECNICAL FIELD

Embodiments of the inventive concept are directed to a semiconductor package, and more particularly, to a semiconductor package in which two dies are directly stacked through wafer-to-wafer bonding.

### DISCUSSION OF THE RELATED ART

Due to the rapid development of the electronics industry and user demand, electronic devices are becoming smaller and lighter. As electronic devices are becoming smaller and lighter, semiconductor packages used therein are also becoming smaller and lighter, and such a semiconductor package should be highly integrated and have high-speed. In response to these demands, semiconductor packages that include stacked semiconductor chips are being developed.

### SUMMARY

Embodiments of the inventive concept provide a semiconductor package with stacked semiconductor chips and increased structural reliability.

According to an embodiment of the inventive concept, there is provided a semiconductor package that includes a first semiconductor chip that includes a first semiconductor substrate that includes an active surface and an inactive surface opposite to each other and a plurality of first through silicon vias that penetrate through the first semiconductor substrate, a plurality of second semiconductor chips that each include a second semiconductor substrate that includes an active surface and an inactive surface opposite to each other and a plurality of second through silicon vias that penetrate through the second semiconductor substrate, where each of the plurality of second semiconductor chips is stacked on the first semiconductor chip, such that the active surface of each second semiconductor substrate faces the inactive surface of the first semiconductor substrate, and the plurality of second semiconductor chips have the same vertical height, a plurality of bonding pads interposed between the first semiconductor chip and the plurality of second semiconductor chips and that electrically interconnect the plurality of first through silicon vias and the plurality of second through silicon vias, and a chip bonding insulation layer that surrounds the plurality of bonding pads and is interposed between the first semiconductor chip and the plurality of second semiconductor chips. The first semiconductor substrate includes a stress reduction member that fills a trench formed in the inactive surface and that extends toward the active surface and overlaps the plurality of second semiconductor chips in a vertical direction perpendicular to the inactive surface.

According to another embodiment of the inventive concept, there is provided a semiconductor package that includes a high-bandwidth memory (HBM) control die that includes a first semiconductor substrate that includes an active surface and an inactive surface opposite to each other and a plurality of first through silicon vias that penetrate through at least a portion of the first semiconductor substrate, a plurality of dynamic random access memory (DRAM) dies that each include a second semiconductor substrate that includes an active surface and an inactive surface opposite to each other and a plurality of second through silicon vias that penetrate through the second semiconductor substrate, wherein each of the plurality of DRAM dies is stacked on the HBM control die such that the active surface of each second semiconductor substrate faces the inactive surface of the first semiconductor substrate, and the plurality of DRAM dies have the same vertical height, a plurality of bonding pads interposed between the HBM control die and the plurality of DRAM dies and that electrically interconnects the plurality of first through silicon vias and the plurality of second through silicon vias, a chip bonding insulation layer that surrounds the plurality of bonding pads and is interposed between the HBM control die and the plurality of DRAM dies, and a package molding layer that covers a top surface of the HBM control die and surrounds side surfaces of the plurality of DRAM dies. The HBM control die includes a stress reduction member that fills a trench formed in the inactive surface and that extends toward the active surface of the first semiconductor substrate and overlaps the plurality of DRAM dies in a vertical direction perpendicular to the inactive surface of the first semiconductor substrate. The stress reduction member includes a first portion that overlaps the plurality of DRAM dies in the vertical direction and has a first width in the horizontal direction and a second portion that overlaps the package molding layer in the vertical direction and has a second width in the horizontal direction, where the second width is greater than or equal to the first width.

According to another embodiment of the inventive concept, there is provided a semiconductor package that includes a base redistribution layer that includes a plurality of package redistribution line patterns, a plurality of package redistribution vias that contact and are connected to at least some of the plurality of package redistribution line patterns, and a package redistribution insulation layer that surrounds the plurality of package redistribution line patterns and the plurality of package redistribution vias, an HBM control die that includes a first semiconductor substrate that includes a first active surface and a first inactive surface opposite to each other and a plurality of first through silicon vias that penetrate through the first semiconductor substrate, where the HBM control die is disposed on the base redistribution layer such that the first inactive surface faces the base redistribution layer, a plurality of DRAM dies that each include a second semiconductor substrate that includes a second active surface and a second inactive surface opposite to each other and a plurality of second through silicon vias that penetrate through the second semiconductor substrate, where each of the plurality of DRAM dies is stacked on the HBM control die such that each second active surface faces the first inactive surface, and the plurality of DRAM dies have the same vertical height and a horizontal width identical to a horizontal width of the HBM control die, a plurality of bonding pads interposed between the HBM control die and the plurality of DRAM dies and that electrically interconnects the plurality of first through silicon vias and the plurality of second through silicon vias, a chip bonding insulation layer that surrounds the plurality of bonding pads and that are interposed between the HBM control die and the plurality of DRAM dies, a support dummy substrate stacked on the plurality of DRAM dies, and a package molding layer disposed on the HBM control die and that covers a top surface of the HBM control die and side surfaces of the plurality of DRAM dies, and exposes a top surface of the support dummy substrate without covering the top surface of the support dummy substrate. The HBM control die includes a stress reduction member that fills a trench formed in the first inactive surface and that extends toward the first active surface and overlaps the plurality of DRAM dies in a vertical direction perpendicular to the inactive surface. The stress reduction member includes a first portion that overlaps the plurality of DRAM dies in the vertical direction and that has a first width in the horizontal direction, and a second portion that overlaps the package molding layer in the vertical direction and that has a second width in the horizontal direction, where the second width is greater than or equal to the first width.

### BRIEF DESCRIPTION OF THE DRAWINGS

FIG. 1 is a plan view of a semiconductor package according to an embodiment.

FIG. 2 is a cross-sectional view taken along a line A-A′ in FIG. 1.

FIG. 3 is an enlarged view of a region Pa of FIG. 2.

FIG. 4 is an enlarged view of a semiconductor package according to an embodiment and is an enlarged view that corresponds to the region Pa of FIG. 2.

FIG. 5 is a cross-sectional view of a semiconductor package according to an embodiment.

FIG. 6 is an enlarged view of a region Pc of FIG. 5.

FIG. 7 is a plan view of a semiconductor package according to an embodiment.

FIG. 8 is a plan view of a semiconductor package according to an embodiment.

FIG. 9 is a plan view of a semiconductor package according to an embodiment.

FIGS. 10 to 21 are cross-sectional views that illustrate a method of manufacturing a semiconductor package according to an embodiment.

### DETAILED DESCRIPTION

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

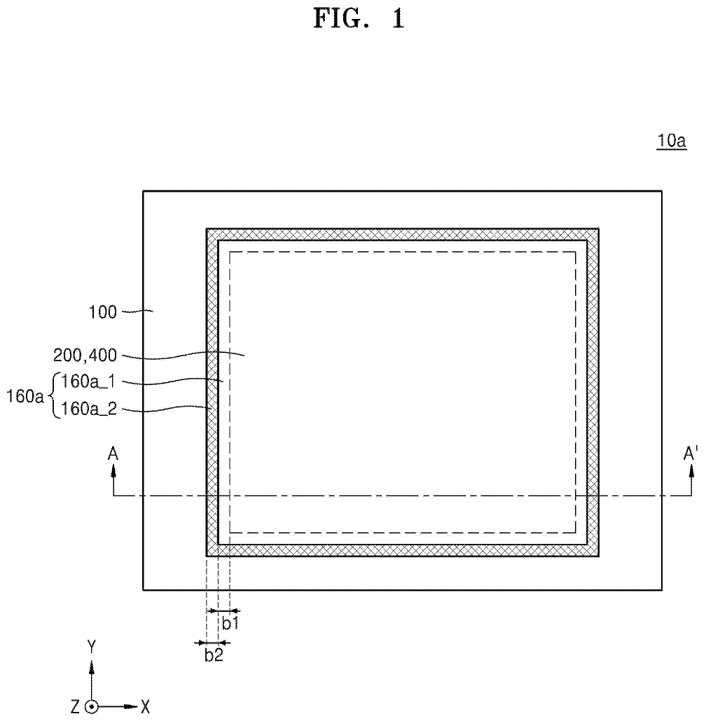

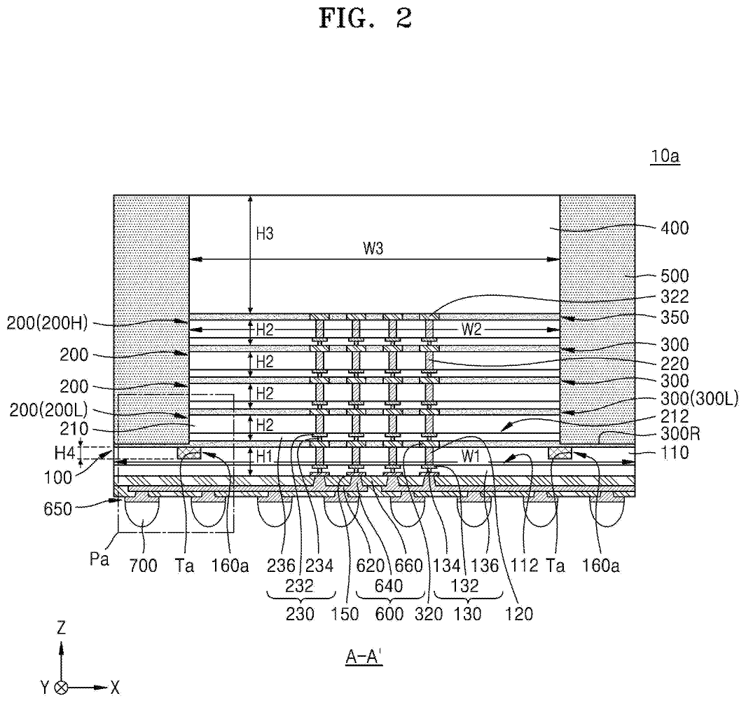

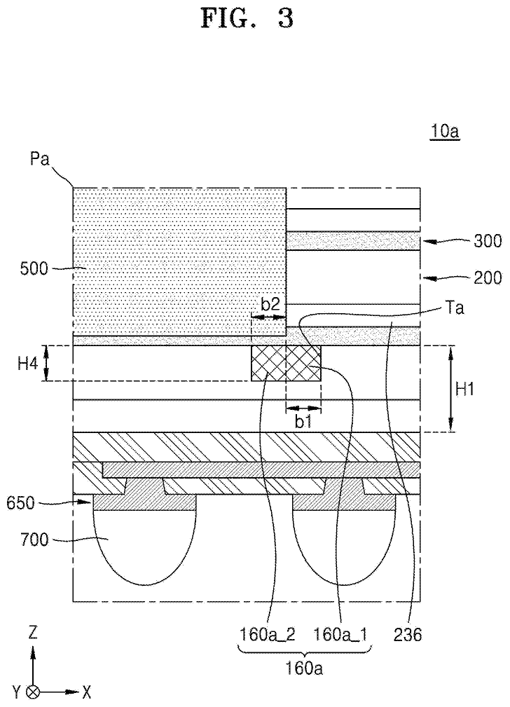

FIG. 1 is a plan view of a semiconductor package according to an embodiment, and FIG. 2 is a cross-sectional view taken along a line A-A′ of FIG. 1. FIG. 3 is an enlarged view of a region Pa of FIG. 2.

Referring to FIGS. 1 to 3, in an embodiment, a semiconductor package 10a includes a first semiconductor chip 100 and a plurality of second semiconductor chips 200. Although FIG. 2 shows that the semiconductor package 10a includes four second semiconductor chips 200, embodiments of the inventive concept are not necessarily limited thereto. For example, in some embodiments, the semiconductor package 10a includes two or more second semiconductor chips 200. In some embodiments, the number of second semiconductor chips 200 in the semiconductor package 10a is a multiple of 4. The second semiconductor chips 200 are sequentially stacked on the first semiconductor chip 100. For convenience of explanation, the second semiconductor chip 200 located at the bottom of the plurality of second semiconductor chips 200 may be referred to as a lowermost second semiconductor chip 200L, and the second semiconductor chip 200 located at the top of the plurality of second semiconductor chips 200 may be referred to as an uppermost second semiconductor chip 200H. In this specification, a direction perpendicular to the top surface of the first semiconductor chip 100 may be defined as a vertical direction (Z direction), and a direction parallel to the top surface of the first semiconductor chip 100 and in which a plurality of first through silicon via 120 are sequentially arranged may be defined as a first horizontal direction (X direction). Also, a direction perpendicular to the first horizontal direction (X direction) may be defined as a second horizontal direction (Y direction).

The first semiconductor chip 100 and the plurality of second semiconductor chips 200 in the semiconductor package 10a are electrically connected through a plurality of bonding pads 320, exchange signals with each other, and provide power and ground to each other. For example, the plurality of bonding pads 320 are arranged between the first semiconductor chip 100 and the lowermost second semiconductor chip 200L and between adjacent second semiconductor chips 200.

For example, the plurality of bonding pads 320 include a material that contains Cu. Of the plurality of bonding pads 320, a bonding pad 320 between the first semiconductor chip 100 and the lowermost second semiconductor chip 200L may be referred to as a first bonding pad, and a bonding pad 320 between two adjacent semiconductor chips 200 may be referred to as a second bonding pad.

The first semiconductor chip 100 includes a first semiconductor substrate 110 that includes an active surface and an inactive surface opposite to each other, a first semiconductor device 112 formed on the active surface of the first semiconductor substrate 110, a first wiring structure 130 formed on the active surface of the first semiconductor substrate 110, and a plurality of first through silicon via 120 connected to the first wiring structure 130 and that penetrate through at least a portion of the first semiconductor chip 100. The first semiconductor chip 100 further includes a plurality of chip pads 150 arranged on the bottom surface of the first semiconductor chip 100 and electrically connected to a first wiring pattern 132 and/or first wiring vias 134. The plurality of chip pads 150 are electrically connected to the first semiconductor device 112 or the first wiring structure 130 through the first wiring pattern 132 and/or the first wiring vias 134.

In the first semiconductor chip 100 of the semiconductor package 10a, the active surface of the first semiconductor substrate 110 faces downward and a non-active surface faces upward. Therefore, unless stated otherwise in the present specification, the top surface of the first semiconductor chip 100 of the semiconductor package 10a refers to a side toward which the inactive surface of the first semiconductor substrate 110 faces, and the bottom surface of the first semiconductor chip 100 of the semiconductor package 10a refers to a side toward which the inactive surface of the first semiconductor substrate 110 faces. In addition, the bottom surface of the first semiconductor chip 100 that faces the active surface of the first semiconductor substrate 110 may be referred to as the front surface of the first semiconductor chip 100, and the top surface of the first semiconductor chip 100 that faces the non-active surface may be referred to as the rear surface of the first semiconductor chip 100.

The second semiconductor chip 200 includes a second semiconductor substrate 210 that includes an active surface and an inactive surface opposite to each other, a second semiconductor device 212 formed on the active surface of the second semiconductor substrate 210, and a second wiring structure 230 formed on the active surface of the second semiconductor substrate 210.

Each of the plurality of second semiconductor chips 200 further includes a plurality of second through silicon via 220 that are connected to the second wiring structure 230 and penetrate through at least a portion of the second semiconductor chip 200.

According to some embodiments, a plurality of top surface chip connection pads 322 arc arranged on the top surface of the uppermost second semiconductor chip 200H. The plurality of top surface chip connection pads 322 are arranged on the top surface of the second semiconductor chip 200 and are connected to the plurality of second through silicon via 220.

According to some embodiments, of the plurality of second semiconductor chips 200, the vertical height, such as a thickness, of the uppermost second semiconductor chip 200H and the vertical height, such as a thickness, of the remaining second semiconductor chips 200 have substantially the same value.

Within the semiconductor package 10a, the second semiconductor chips 200 are sequentially stacked on the first semiconductor chip 100 in the vertical direction (Z direction) while the active surfaces thereof face downward toward the first semiconductor chip 100. Therefore, unless stated otherwise in the present specification, the top surface of the second semiconductor chip 200 of the semiconductor package 10a refers to a side toward which the inactive surface of the second semiconductor substrate 210 faces, and the bottom surface of the second semiconductor chip 200 of the semiconductor package 10a refers to a side toward which the inactive surface of the second semiconductor substrate 210 faces. In addition, the bottom surface of the second semiconductor chip 200 that faces the active surface of the second semiconductor substrate 210 may be referred to as the front surface of the second semiconductor chip 200, and the top surface of the second semiconductor chip 200 that faces the non-active surface may be referred to as the rear surface of the second semiconductor chip 200.

In some embodiments, the first semiconductor substrate 110 and the second semiconductor substrate 210 include a semiconductor material such as silicon (Si). In some embodiments, the first semiconductor substrate 110 and the second semiconductor substrate 210 include a semiconductor material such as germanium (Ge). The first semiconductor substrate 110 and the second semiconductor substrate 210 each have an active surface and an inactive surface opposite to the active surface. The first semiconductor substrate 110 and the second semiconductor substrate 210 each include a conductive region, such as a well doped with impurities. The first semiconductor substrate 110 and the second semiconductor substrate 210 include various device isolation structures, such as a shallow trench isolation (STI) structure.

The first semiconductor device 112 and the second semiconductor device 212 each include a plurality of various types of individual devices. The individual devices may include any of various microelectronic devices, such as a metal-oxide-semiconductor field effect transistor (MOSFET) such as a complementary metal-insulator-semiconductor transistor (CMOS transistor), a system large scale integration (LSI), an image sensor such as a CMOS imaging sensor (CIS), a micro-electro-mechanical system (MEMS), an active device, a passive device, etc. The individual devices are electrically connected to the conductive region of the first semiconductor substrate 110 or second semiconductor substrate 210. The first semiconductor device 112 and the second semiconductor device 212 each further include a conductive wire or a conductive plug that electrically connects at least two of the individual devices or all of the individual devices to respective conductive regions of the first semiconductor substrate 110 and the second semiconductor substrate 210. In addition, the individual devices are each electrically separated from each other by an insulating film.

At least one of the first semiconductor chip 100 or the second semiconductor chip 200 is a memory semiconductor chip. According to some embodiments, the first semiconductor chip 100 includes a serial-parallel conversion circuit and is a buffer chip that controls the plurality of second semiconductor chips 200, and the semiconductor chips 200 are memory chips that include memory cells. For example, the semiconductor package 10a that includes the first semiconductor chip 100 and the plurality of second semiconductor chips 200 is a high bandwidth memory (HBM), in which the first semiconductor chip 100 may be referred to as an HBM controller die, and each of the plurality of second semiconductor chips 200 may be referred to as a dynamic random access memory (DRAM) die.

The first wiring structure 130 includes a plurality of first wiring patterns 132, a plurality of first wiring vias 134 connected to the plurality of first wiring patterns 132, and a first inter-wire insulation layer 136 that surrounds the plurality of first wiring patterns 132 and the plurality of first wiring vias 134. According to some embodiments, the plurality of first wiring patterns 132 have a thickness of about 0.5 micrometers or less. According to some embodiments, the first wiring structure 130 has a multi-layer wiring structure that includes first wiring patterns 132 and the first wiring vias 134 located at different vertical levels.

The second wiring structure 230 includes a plurality of second wiring patterns 232, a plurality of second wiring vias 234 connected to the plurality of second wiring patterns 232, and a second inter-wire insulation layer 236 that surrounds the plurality of second wiring patterns 232 and the plurality of second wiring vias 234. According to some embodiments, the plurality of second wiring patterns 232 have a thickness of about 0.5 micrometers or less. According to some embodiments, the second wiring structure 230 has a multi-layer wiring structure that includes the second wiring patterns 232 and the second wiring vias 234 located at different vertical levels.

The plurality of first wiring patterns 132, the plurality of first wiring vias 134, the plurality of second wiring patterns 232, and the plurality of second wiring vias 234 include a metal, such as aluminum, copper, or tungsten. According to some embodiments, the plurality of first wiring patterns 132, the plurality of first wiring vias 134, the plurality of second wiring patterns 232, and the plurality of second wiring vias 234 each include a wiring barrier film and a wiring metal layer. The wiring barrier film includes at least one of a metal, a metal nitride, or an alloy. The wiring metal layer includes at least one of W, Al, Ti, Ta, Ru, Mn, or Cu.

When the first wiring structure 130 and the second wiring structure 230 have a multi-layer wiring structure, the first inter-wire insulation layer 136 and the second inter-wire insulation layer 236 have a multi-layer structure in which a plurality of insulation layers are stacked in correspondence to the multi-layer wiring structure of the first wiring structure 130 and the second wiring structure 230. For example, the first inter-wire insulation layer 136 and the second inter-wire insulation layer 236 include one or more of silicon oxide, silicon nitride, silicon oxynitride, an insulation material with a lower dielectric constant than silicon oxide, or a combination thereof. According to some embodiments, the first inter-wire insulation layer 136 and the second inter-wire insulation layer 236 include a tetraethyl orthosilicate (TEOS) film or a ultra-low K (ULK) film that has an ultra-low dielectric constant K from about 2.2 to about 2.4. The ULK film includes one of an SiOC film or a SiCOH film.

The first through silicon via 120 and the second through silicon via 220 are through silicon vias (TSVs). The first through silicon via 120 and the second through silicon via 220 each include a conductive plug that penetrates through the first semiconductor substrate 110 or the second semiconductor substrate 210 and a conductive barrier film that surrounds the conductive plug. The conductive plug has a cylindrical shape, and the conductive barrier film has a cylindrical shape that surrounds the sidewall of the conductive plug. Via insulation films are interposed between the first via electrode 120 and the first semiconductor substrate 110 and between the second via electrode 220 and the second semiconductor substrate 210, thereby surrounding the sidewalls of the first via electrode 120 and the second via electrode 220. The first via electrode 120 and the second via electrode 220 have one of a via-first structure, a via-middle structure, or via-last structure.

The first semiconductor chip 100 has a first horizontal width W1 and a first vertical height H1, and the plurality of second semiconductor chips 200 each have a second horizontal width W2 and a second vertical height H2. According to some embodiments, the first horizontal width W1 is greater than the second horizontal width W2. According to some embodiments, the first vertical height H1 and the second vertical height H2 have substantially the same value. For example, the first vertical height Hl and the second vertical height H2 is each from about 50 micrometers to about 70 micrometers.

The plurality of bonding pads 320 electrically connect the second wiring patterns 232 and/or the second wiring vias 234 of the second wiring structure 230 to the plurality of first through silicon via 120 or the plurality of second wiring vias 234 therebelow.

For example, the second wiring patterns 232 and/or the second wiring vias 234 of the second wiring structure 230 in the lowermost second semiconductor chip 200L are electrically connected to the plurality of first through silicon via 120 in the first semiconductor chip 100 therebelow through the plurality of bonding pads 320, such as a plurality of first bonding pads, and the second wiring patterns 232 and/or the second wiring vias 234 of the second wiring structure 230 in the semiconductor chip 200 other than the lowermost second semiconductor chip 200L are electrically connected to the plurality of second through silicon via 220 in another second semiconductor chip 200 therebelow through the plurality of bonding pads 320, such as a plurality of second bonding pads.

Between the first semiconductor chip 100 and the plurality of second semiconductor chips 200, for example, between the first semiconductor chip 100 and the lowermost second semiconductor chip 200L, and between the plurality of second semiconductor chips 200, the plurality of bonding pads 320 are surrounded by chip bonding insulation layers 300. The plurality of bonding pads 320 penetrate through the chip bonding insulation layer 300. A plurality of chip bonding insulation layers 300 are provided between the first semiconductor chip 100 and the plurality of second semiconductor chips 200.

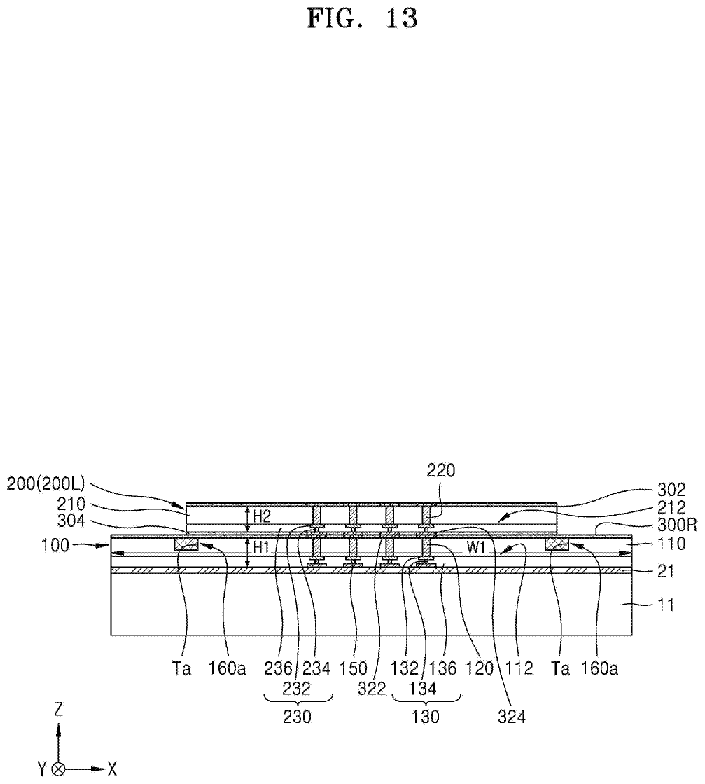

The plurality of bonding pads 320 are formed by forming conductive material layers, such as the plurality of top surface chip connection pads 322 and a plurality of bottom surface chip connection pads 324 shown in FIG. 13, on surfaces of two chips, such as the first semiconductor chip 100 and an adjacent second semiconductor chip 200 that face each other and diffusion-bonding the conductive material layers that face each other to contact each other through thermal expansion and to be integrated with each other through diffusion of metal atoms therein.

The chip bonding insulation layer 300 is formed by forming insulation material layers, such as a top surface chip bonding insulation layer 302 and a bottom surface chip bonding insulation layer 304 shown in FIGS. 13 to 16, on surfaces of two chips, such as the first semiconductor chip 100 and an adjacent second semiconductor chip 200 that face each other and diffusion-bonding the insulation material layers that face each other to contact each other through thermal bonding and to be integrated with each other through diffusion of metal atoms therein in the process of formation of the plurality of bonding pads 320.

Of the plurality of chip bonding insulation layers 300, a lowermost chip bonding insulation layer 300L disposed between the first semiconductor chip 100 and the lowermost second semiconductor chip 200L is formed as an insulation material layer that covers the top surface of the first semiconductor chip 100 and the bottom surface of the lowermost second semiconductor chip 200L, such that a lowermost top surface chip bonding insulation material layer 302L and the bottom surface chip bonding insulation layer 304 are diffusion-bonded to each other.

The lowermost chip bonding insulation layer 300L has a first recess 300R in an upper portion of the lowermost chip bonding insulation layer 300L, such that the thickness of a portion of the lowermost chip bonding insulation layer 300L that overlaps the lowermost second semiconductor chip 200L in the vertical direction is greater than the thickness of a portion of the lowermost chip bonding insulation layer 300L that does not overlap the lowermost second semiconductor chip 200L in the vertical direction. The first recess 300R is located in a portion of the lowermost chip bonding insulation layer 300L that does not overlap the lowermost second semiconductor chip 200L in the vertical direction. The lowermost chip bonding insulation layer 300L has a shape in which a center portion, such as the portion of the lowermost chip bonding insulation layer 300L that overlaps the lowermost second semiconductor chip 200L in the vertical direction, protrudes upward from an edge portion, such as the portion of the lowermost chip bonding insulation layer 300L that does not overlap the lowermost second semiconductor chip 200L in the vertical direction, and has a flat bottom surface.

The lowermost chip bonding insulation layer 300L covers all portions of the top surface of the first semiconductor chip 100 that do not overlap the lowermost second semiconductor chip 200L in the vertical direction. A portion of the top surface of the first semiconductor chip 100 that overlaps the lowermost second semiconductor chip 200L in the vertical direction and a portion of the bottom surface of the lowermost second semiconductor chip 200L are covered by the plurality of bonding pads 320, and the remaining portion of the bottom surface of the lowermost second semiconductor chip 200L is covered by the lowermost chip bonding insulation layer 300L.

The remaining chip bonding insulation layers 300 other than the lowermost chip bonding insulation layer 300L cover both the top surface and the bottom surface of the second semiconductor chip 200 that face each other, together with the plurality of bonding pads 320. The remaining chip bonding insulation layers 300 other than the lowermost chip bonding insulation layer 300L have flat top surfaces and flat bottom surfaces and have substantially the same thickness.

A support dummy substrate 400 is stacked on the uppermost second semiconductor chip 200H. The support dummy substrate 400 includes, for example, a semiconductor material such as silicon (Si). According to some embodiments, the support dummy substrate 400 includes only semiconductor materials. For example, the support dummy substrate 400 is a portion of a bare wafer.

The support dummy substrate 400 has a third horizontal width W3 and a third vertical height H3. According to some embodiments, the third horizontal width W3 is less than the first horizontal width W1 and the second horizontal width W2. According to some embodiments, the third horizontal width W3 and the second horizontal width W2 are equal to each other. According to some embodiments, the third vertical height H3 is greater than the first vertical height H1 and the second vertical height H2. For example, the third vertical height H3 is from about 100 micrometers to about 500 micrometers.

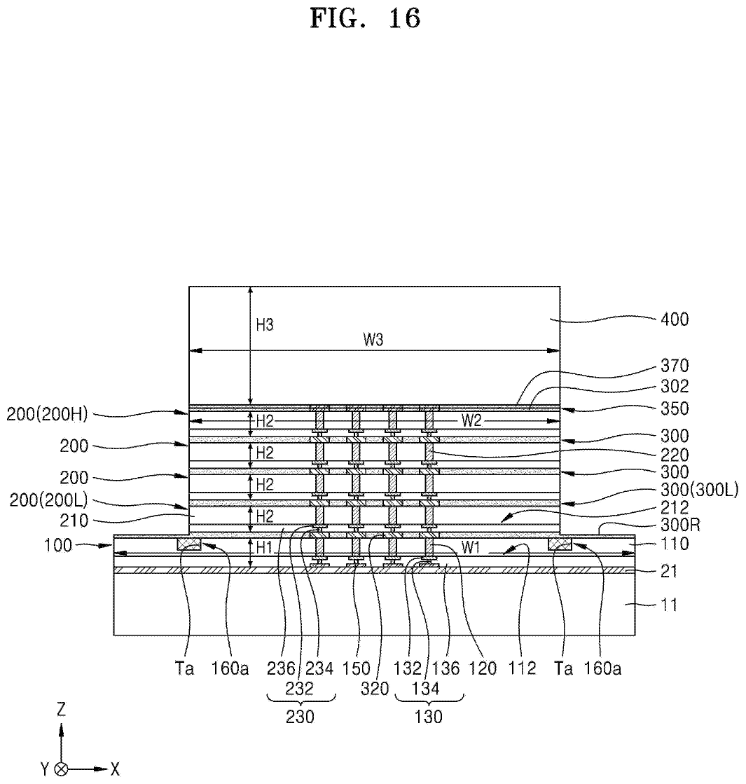

A support bonding insulation layer 350 is interposed between the uppermost second semiconductor chip 200H and the support dummy substrate 400. The support bonding insulation layer 350 is formed by forming insulation material layers, such as the top surface chip bonding insulation layer 302 and a bottom surface dummy bonding insulation material layer 364 shown in FIG. 16, on the top surface of the uppermost second semiconductor chip 200H and the bottom surface of the support dummy substrate 400 that face each other and diffusion-bonding the insulation material layers to each other, such that the insulation material layers that face each other contact each other through thermal expansion and are integrated with each other through diffusion of atoms therein.

A semiconductor material is exposed on the bottom surface of the support dummy substrate 400. Therefore, the top surface of the support bonding insulation layer 350 contacts the semiconductor material. The support bonding insulation layer 350 covers the entire bottom surface of the support dummy substrate 400. According to some embodiments, when the plurality of top surface chip connection pads 322 are arranged on the top surface of the uppermost second semiconductor chip 200H, the support bonding insulation layer 350 surrounds the plurality of top surface chip connection pads 322. For example, the support bonding insulation layer 350 covers the top surface, such as the inactive surface, of the second semiconductor substrate 210 of the uppermost second semiconductor chip 200H and side surfaces and top surfaces of the plurality of top surface chip connection pads 322. The plurality of top surface chip connection pads 322 are spaced apart from the support dummy substrate 400 with the support bonding insulation layer 350 interposed therebetween. According to some embodiments, when the plurality of top surface chip connection pads 322 are not arranged on the top surface of the uppermost second semiconductor chip 200H, the support bonding insulation layer 350 covers the top surface of the second semiconductor substrate 210 of the uppermost second semiconductor chip 200H and the plurality of second through silicon via 220 exposed on the top surface of the second semiconductor substrate 210 of the uppermost second semiconductor chip 200H. In an embodiment, the support bonding insulation layer 350 covers the entire top surface of the second semiconductor substrate 210 of the uppermost second semiconductor chip 200H.

The lowermost chip bonding insulation layer 300L has the first horizontal width W1, and the remaining chip bonding insulation layers 300 other than the lowermost chip bonding insulation layer 300L and the support bonding insulation layer 350 have the second horizontal width W2. The remaining chip bonding insulation layers 300 other than the lowermost chip bonding insulation layer 300L overlap the plurality of second semiconductor chips 200 in the vertical direction. Side surfaces of the remaining chip bonding insulation layers 300 other than the lowermost chip bonding insulation layer 300L and side surfaces of the plurality of second semiconductor chips 200 are aligned with each other in the vertical direction and are coplanar with each other.

The chip bonding insulation layer 300 and the support bonding insulation layer 350 each include one of SiO, SIN, SiCN, SiCO, or a polymer material. The polymer material is at least one of benzocyclobutene (BCB), polyimide (PI), polybenzoxazole (PBO), silicone, acrylate, or epoxy. For example, the chip bonding insulation layer 300 and the support bonding insulation layer 350 each include silicon oxide. According to some embodiments, the chip bonding insulation layer 300 and the support bonding insulation layer 350 include the same material. The chip bonding insulation layer 300 and the support bonding insulation layer 350 each have a thickness, for example, from about 100 nanometers to about 1 micrometer.

The semiconductor package 10a further includes a package molding layer 500 disposed on the first semiconductor chip 100 and that covers the top surface of the first semiconductor chip 100 and surrounds side surfaces of the plurality of second semiconductor chips 200 and the support dummy substrate 400. The package molding layer 500 includes, for example, an epoxy mold compound (EMC). According to some embodiments, the package molding layer 500 covers the top surface of the support dummy substrate 400. According to some other embodiments, the package molding layer 500 does not cover the top surface of the support dummy substrate 400. For example, a heat dissipation member is attached to the support dummy substrate 400 with a thermal interface material (TIM) therebetween.

According to some embodiments, the semiconductor package 10a further includes a base redistribution layer 600 disposed on the bottom surface of the first semiconductor chip 100. The base redistribution layer 600 includes a plurality of package redistribution line patterns 620, a plurality of package redistribution vias 640, and a package redistribution insulation layer 660. According to some embodiments, a plurality of package redistribution insulation layers 660 are stacked. The package redistribution insulation layer 660 includes, for example, at least one of a photo imageable dielectric (PID) or a photosensitive polyimide (PSPI). The package redistribution line patterns 620 and the package redistribution vias 640 include a metal such as at least one of copper (Cu), aluminum (Al), tungsten (W), titanium (Ti), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or an alloy thereof. However, embodiments of the inventive concept are not necessarily limited thereto. According to some embodiments, a package redistribution line pattern 620 and a package redistribution via 640 are formed by stacking a metal or a metal alloy on a seed layer containing one of titanium, titanium nitride, or titanium tungsten.

The plurality of package redistribution line patterns 620 are arranged on at least one of the top surface or the bottom surface of the package redistribution insulation layer 660. The plurality of package redistribution vias 640 penetrate through the package redistribution insulation layer 660 and are connected to at least some of the plurality of package redistribution line patterns 620. According to some embodiments, at least some of the plurality of package redistribution line patterns 620 are formed together and integrated with some of the plurality of package redistribution vias 640. For example, the package redistribution line patterns 620 and the package redistribution vias 640 that contacting the top surface of the package redistribution line pattern 620 are integrated with each other. The package redistribution insulation layer 660 surrounds the plurality of package redistribution line patterns 620 and the plurality of package redistribution vias 640.

The plurality of package redistribution line patterns 620 and the plurality of package redistribution vias 640 are electrically connected to the plurality of chip pads 150. According to some embodiments, at least some of the plurality of package redistribution vias 640 contact the plurality of chip pads 150. For example, when the base redistribution layers 600 includes the plurality of stacked package redistribution insulation layers 660, a package redistribution via 640 that penetrates through the uppermost package redistribution insulation layer 660 contacts and is electrically connected to a chip pad 150.

According to some embodiments, the plurality of package redistribution vias 640 have a tapered shape in which the horizontal width thereof decreases along the vertical direction toward the chip pads 150. For example, the horizontal width of the plurality of package redistribution vias 640 increases in a direction away from the first semiconductor chip 100.

Of the plurality of package redistribution line patterns 620, those disposed on the bottom surface of the base redistribution layer 600 may be referred to as a package pad 650. A plurality of package connection terminals 700 are attached to a plurality of package pads 650. For example, a package connection terminal 700 may be a solder ball or a bump.

According to some embodiments, the semiconductor package 10a does not include the base redistribution layer 600. In some embodiments, the plurality of package connection terminals 700 are attached to the plurality of chip pads 150.

The horizontal width and horizontal area of the base redistribution layer 600 have the same values as the horizontal width and horizontal area of the first semiconductor chip 100. The base redistribution layer 600 and the first semiconductor chip 100 overlap each other in the vertical direction (Z direction).

For example, the horizontal widths and horizontal areas of the base redistribution layer 600, the first semiconductor chip 100, and the package molding layer 500 have substantially the same values. Side surfaces of the base redistribution layer 600, the first semiconductor chip 100, and the package molding layer 500 are aligned with one another in the vertical direction (Z direction) and coplanar with one another.

The semiconductor package 10a according to an embodiment of the inventive concept is formed by stacking the first semiconductor chip 100 and the plurality of second semiconductor chips 200 through a hybrid bonding in which the plurality of bonding pads 320 and the chip bonding insulation layer 300 are formed through diffusion-bonding.

Since the semiconductor package 10a according to an embodiment of the inventive concept includes the relatively thick support dummy substrate 400, the structural reliability of the semiconductor package 10a is increased, and heat smoothly dissipates out from the semiconductor package 10a through the support dummy substrate 400. The support dummy substrate 400 and the uppermost second semiconductor chip 200H are bonded to each other by the support bonding insulation layer 350, and the top surface and the bottom surface of the support bonding insulation layer 350 contact semiconductor materials that constitute the support dummy substrate 400 and the uppermost second semiconductor chip 200H.

In the semiconductor package 10a according to an embodiment of the inventive concept, the plurality of second semiconductor chips 200 therein are all formed through a same process, and thus the process can be simplified and the manufacturing cost can be reduced.

According to an embodiment, the first semiconductor substrate 110 includes a stress reduction member 160a that fills a trench Ta formed in an inactive surface and that extends toward an active surface. The stress reduction member 160a overlaps edges of the plurality of second semiconductor chips 200 and the support dummy substrate 400 in the vertical direction (Z direction) when viewed from above. The stress reduction member 160a include a first portion 160a_1 that overlaps the plurality of second semiconductor chips 200 and/or the support dummy substrate 400 in the vertical direction (Z direction), and a second portion 160a_2 that does not overlap the plurality of second semiconductor chips 200 or the support dummy substrate 400 in the vertical direction (Z direction). Since side surfaces of the plurality of second semiconductor chips 200 and the support dummy substrate 400 are aligned in the vertical direction (Z direction) and coplanar with each other, the first portion 160a_1 simultaneously overlaps the plurality of second semiconductor chips 200 and the support dummy substrate 400, whereas the second portion 160a_2 overlaps neither the plurality of second semiconductor chips 200 nor the support dummy substrate 400. The second portion 160a_2 overlaps the package molding layer 500 in the vertical direction (Z direction). The side surfaces of the plurality of second semiconductor chips 200 and the support dummy substrate 400 each overlap the stress reduction member 160a when viewed from above.

The first portion 160a_1 of the stress reduction member 160a has a first width b1 in the first horizontal direction (X direction) or the second horizontal direction (Y direction), and the second portion 160a_2 has a second width b2 in the first horizontal direction (X direction) or the second horizontal direction (Y direction). In some embodiments, the first portion 160a_1 of the stress reduction member 160a has a uniform first width b1 in a direction in which the first portion 160a_1 extends. However, according to some embodiments, the first width b1 is not uniform and varies in the first horizontal direction (X direction) or the second horizontal direction (Y direction). According to an embodiment, the first width b1 and the second width b2 are equal to each other.

The first semiconductor chip 100 has a greater area to thickness ratio than each of the plurality of second semiconductor chips 200, which concentrates stress due to expansion or warpage of the package molding layer 500 at the boundary between the first semiconductor chip 100 and the lowermost second semiconductor chip 200L. For example, the stress is concentrated at the boundary between the first semiconductor chip 100 and sidewalls of the lowermost second semiconductor chip 200L when viewed from above. The stress reduction member 160a is formed on the first semiconductor substrate 110 and overlaps the boundary between the sidewalls of the lowermost second semiconductor chip 200L and the first semiconductor chip 100. The stress reduction member 160a includes a material with higher flexibility than the first semiconductor substrate 110 or the second semiconductor substrate 210, which prevents cracks in the first semiconductor substrate 110 due to expansion of the package molding layer 500 or warpage of the semiconductor package 10a.

The stress reduction member 160a includes one or more of a filler, an epoxy molding compound, a polymer, or a combination thereof. The filler includes at least one of silicon oxide (SiO), titanium oxide (TiO), aluminum oxide (AlO), silicon carbide (SiC), boron nitride (BN), or a combination thereof. For example, the filler includes SiO₂. The polymer includes a thermoplastic resin for film formation. For example, the polymer includes at least one of phenoxy resin, PVB resin, or a combination thereof.

When warpage occurs in the semiconductor package 10a, the first semiconductor substrate 110 can be bent convex downward. Therefore, when the first width b1 of the first portion 160a_1 of the stress reduction member 160a is greater than or at least equal to the second width b2 of the second portion 160a_2, the stress reduction member 160a can sufficiently reduce the stress on the first semiconductor substrate 110 that is concentrated at the boundary between the first semiconductor chip 100 and the lowermost second semiconductor chip 200L.

A height H4 of the stress reduction member 160a in the vertical direction (Z direction) is less than or equal to half the height H1 of the first semiconductor substrate 110 in the vertical direction (Z direction). When the height H4 is greater than half the height H1, the thickness of the first semiconductor substrate 110 is reduced, and thus the probability of cracks occurring in the first semiconductor substrate 110 can increase. The height H4 is within the range from about 20 micrometers to about 35 micrometers. When the height H4 is less than about 20 micrometers, the proportion occupied by the stress reduction member 160a within the first semiconductor substrate 110 decreases, and thus the stress reduction member 160a might not properly perform its role of reducing stress on the first semiconductor substrate 110. When the height H4 is greater than about 35 micrometers, the thickness of the first semiconductor substrate 110 is reduced, and thus the probability of cracks occurring in the first semiconductor substrate 110 can increase.

As shown in FIG. 1, the sum of the first width b1 of the first portion 160a_1 of the stress reduction member 160a in the first horizontal direction (X direction) and the second width b2 of the second portion 160a_2 in the first horizontal direction (X direction) is equal to the width of the stress reduction member 160a in the first horizontal direction (X direction). The sum of the first width b1 and the second width b2 is within a range from about 0.7 millimeters to about 1.3 millimeters.

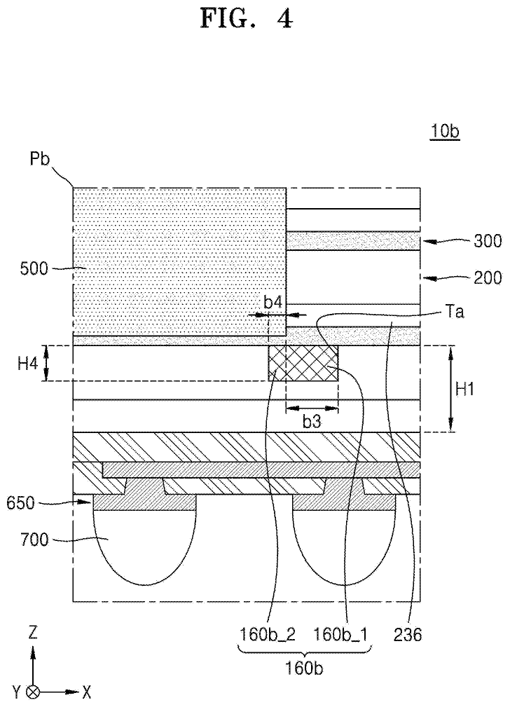

FIG. 4 is an enlarged view of a semiconductor package 10b according to an embodiment and is an enlarged view that corresponds to a region Pa of FIG. 2. The semiconductor package 10b shown in FIG. 4 is substantially similar to the semiconductor package 10a shown in FIGS. 1 to 3 except that an area in which a stress reduction member 160b and the plurality of second semiconductor chips 200 overlap each other differs from that of the semiconductor package 10a. Therefore, repeated descriptions of the components already given above with reference to FIGS. 1 to 3 may be omitted below.

Referring to FIG. 4, in an embodiment, the stress reduction member 160b overlaps edges of the plurality of second semiconductor chips 200 and the support dummy substrate 400 in the vertical direction (Z direction) when viewed from above. The stress reduction member 160b includes a first portion 160b_1 that overlaps the plurality of second semiconductor chips 200 and/or the support dummy substrate 400 in the vertical direction (Z direction), and a second portion 160b_2 that does not overlap the plurality of second semiconductor chips 200 or the support dummy substrate 400 in the vertical direction (Z direction). The second portion 160b_2 overlaps the package molding layer 500 in the vertical direction (Z direction).

The first portion 160b_1 of the stress reduction member 160b has a third width b3 in the first horizontal direction (X direction) or the second horizontal direction (Y direction), and the second portion 160b_2 has a fourth width b4 in the first horizontal direction (X direction) or the second horizontal direction (Y direction). In some embodiments, the first portion 160b_1 of the stress reduction member 160b has a uniform third width b3 in a direction in which the first portion 160b_1 extends. However, according to some embodiments, the third width b3 is not uniform and varies in the first horizontal direction (X direction) or the second horizontal direction (Y direction). The third width b3 is greater than the fourth width b4. The third width b3 is within the range from 1.3 times to 2 times the fourth width b4. When the third width b3 is greater than twice the fourth width b4, portions of the stress reduction member 160b and the package molding layer 500 that overlap in the vertical direction (Z direction) are reduced, and thus the reduction of stress concentrated on the semiconductor substrate 110 may be insufficient.

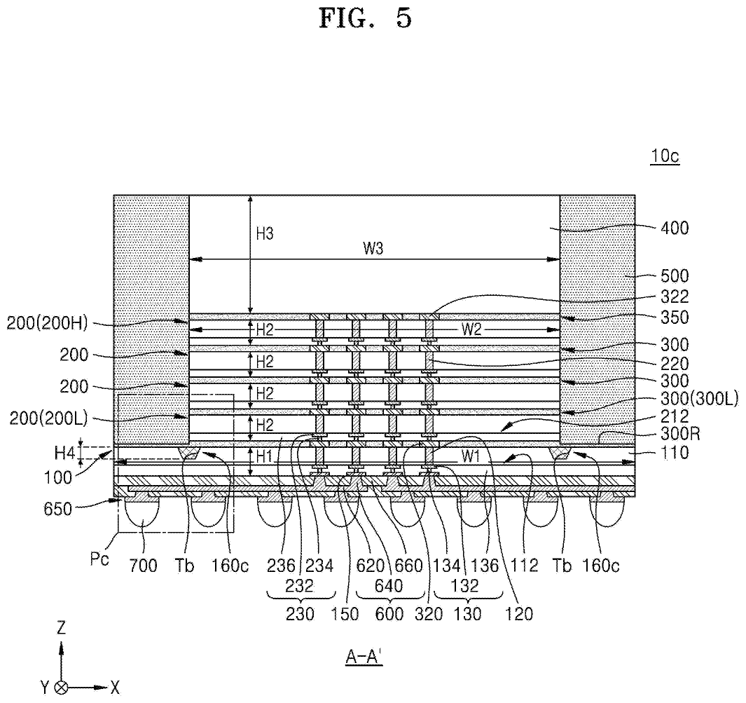

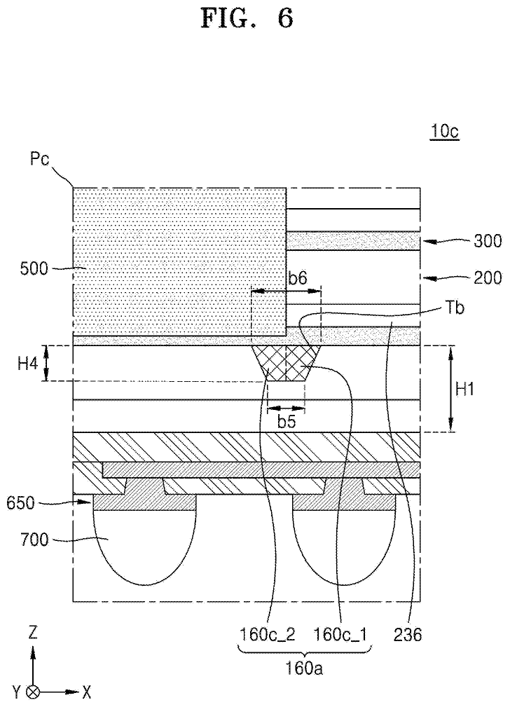

FIG. 5 is a cross-sectional view of a semiconductor package according to an embodiment, and FIG. 6 is an enlarged view of a region Pc of FIG. 5. A semiconductor package 10c shown in FIGS. 5 and 6 is substantially similar to the semiconductor package 10a shown in FIGS. 1 to 3 except that the shape of a stress reduction member 160c differs from that of the semiconductor package 10a. Therefore, repeated descriptions of the components already given above with reference to FIGS. 1 to 3 may be omitted below.

According to an embodiment, the first semiconductor substrate 110 includes the stress reduction member 160c that fills a trench Tb formed in an inactive surface and that extends toward an active surface. Unlike the trench Ta shown in FIGS. 1 to 3, the trench Tb shown in FIGS. 5 and 6 have a tapered shape in which the width thereof becomes narrower in a direction toward the inactive surface of the first semiconductor substrate 110. The trench Tb has an inner wall inclined with respect to the vertical direction (Z direction). The stress reduction member 160c is formed by filling the inside of the trench Tb, and the stress reduction member 160c also has a tapered shape with an outer wall inclined with respect to the vertical direction (Z direction). The area of the top surface of the stress reduction member 160c is greater than the area of the bottom surface of the stress reduction member 160c. A fifth width b5 of the bottom surface of the stress reduction member 160c in the first horizontal direction (X direction) is less than a sixth width b6 of the top surface of the stress reduction member 160c in the first horizontal direction (X direction).

The stress reduction member 160c overlaps edges of the plurality of second semiconductor chips 200 and the support dummy substrate 400 in the vertical direction (Z direction) when viewed from above. The stress reduction member 160c includes a first portion 160c_1 that overlaps the plurality of second semiconductor chips 200 and/or the support dummy substrate 400 in the vertical direction (Z direction), and a second portion 160c_2 that does not overlap the plurality of second semiconductor chips 200 or the support dummy substrate 400 in the vertical direction (Z direction). The second portion 160c_2 overlaps the package molding layer 500 in the vertical direction (Z direction). The outer wall of the first portion 160c_1 is inclined toward the center of the first semiconductor substrate 110, and the outer wall of the second portion 160c_2 is inclined toward an edge of the first semiconductor substrate 110.

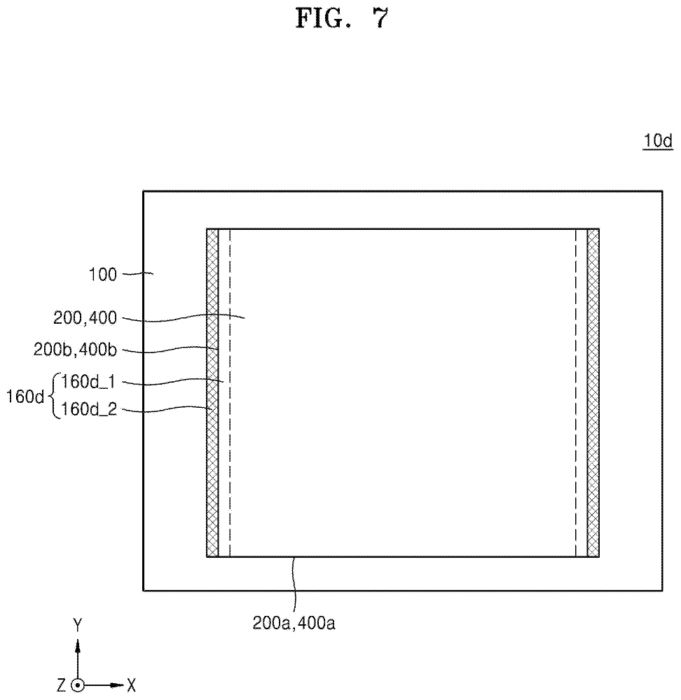

FIG. 7 is a plan view of a semiconductor package according to an embodiment. A semiconductor package 10d shown in FIG. 7 is substantially similar to the semiconductor package 10a shown in FIG. 1 except that the shape of a stress reduction member 160d differs from that of the semiconductor package 10a.

Referring to FIG. 7, in an embodiment, the plurality of second semiconductor chips 200 and the support dummy substrate 400 have first edges 200a and 400a that extend in the first horizontal direction (X direction) and second edges 200b and 400b that extend in the second horizontal direction (Y direction).

The plurality of second semiconductor chips 200 and the support dummy substrate 400 are stacked and overlap each other in the vertical direction (Z direction), where side surfaces of each of the plurality of second semiconductor chips 200 and side surfaces of the support dummy substrate 400 are aligned with each other in the vertical direction (Z direction) and coplanar with each other. Therefore, first edges 200a and second edges 200b of the plurality of second semiconductor chips 200 are aligned with first edges 400a and second edges 400b of the support dummy substrate 400 in the vertical direction (Z direction), respectively.

As shown in FIG. 7, the stress reduction member 160d overlaps the second edges 200b and 400b of the plurality of second semiconductor chips 200 and the support dummy substrate 400 in the vertical direction (Z direction), but does not overlap the first edges 200a and 400a of the plurality of second semiconductor chips 200 and the support dummy substrate 400 in the vertical direction (Z direction). The stress reduction member 160d is formed along the first edges 200a of the plurality of second semiconductor chips 200 and the first edges 400a of the support dummy substrate 400 and not along the second edges 200b of the plurality of second semiconductor chips 200 and the second edges 400b of the support dummy substrate 400. The stress reduction member 160d is symmetrical in the second horizontal direction (Y direction) about the center of the plurality of second semiconductor chips 200 or the support dummy substrate 400 when viewed from above. The stress reduction member 160d includes a first portion 160d_1 that overlaps the plurality of second semiconductor chips 200 and/or the support dummy substrate 400 in the vertical direction (Z direction) and a second portion 160d_2 that does not overlap the plurality of second semiconductor chips 200 or the support dummy substrate 400 in the vertical direction (Z direction). The area of the top surface of the first portion 160d_1 and the area of the top surface of the second portion 160d_2 are substantially equal to each other.

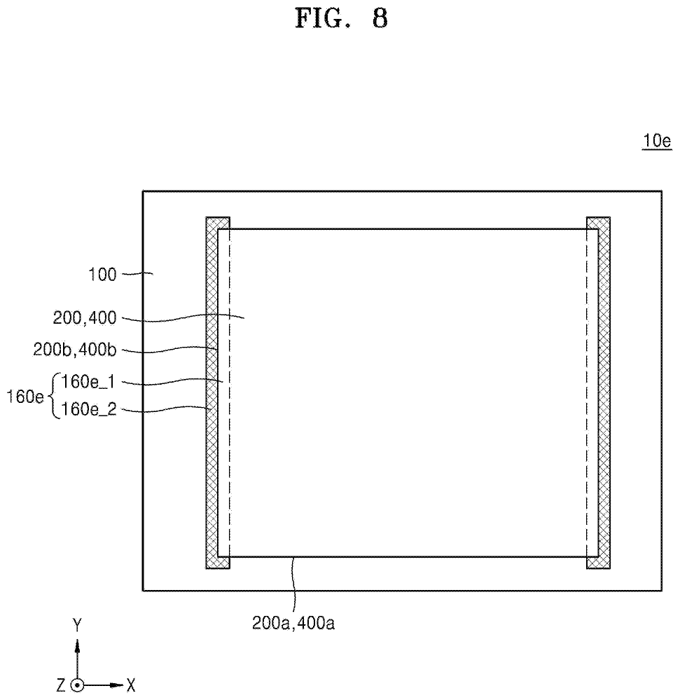

FIG. 8 is a plan view of a semiconductor package according to an embodiment. A semiconductor package 10e shown in FIG. 8 is substantially similar to the semiconductor package 10a shown in FIG. 1 except that the shape of a stress reduction member 160e differs from that of the semiconductor package 10a.

Referring to FIG. 8, in an embodiment, a second portion 160e_2 of the stress reduction member 160e that does not overlap the plurality of second semiconductor chips 200 or the support dummy substrate 400 in the vertical direction (Z direction) protrudes from first edges 200a and 400a of the plurality of second semiconductor chips 200 and the support dummy substrate 400 in the second horizontal direction (Y direction). Therefore, unlike the semiconductor package 10d shown in FIG. 7, the area of the top surface of the second portion 160e_2 is greater than the area of the top surface the first portion 160e_1.

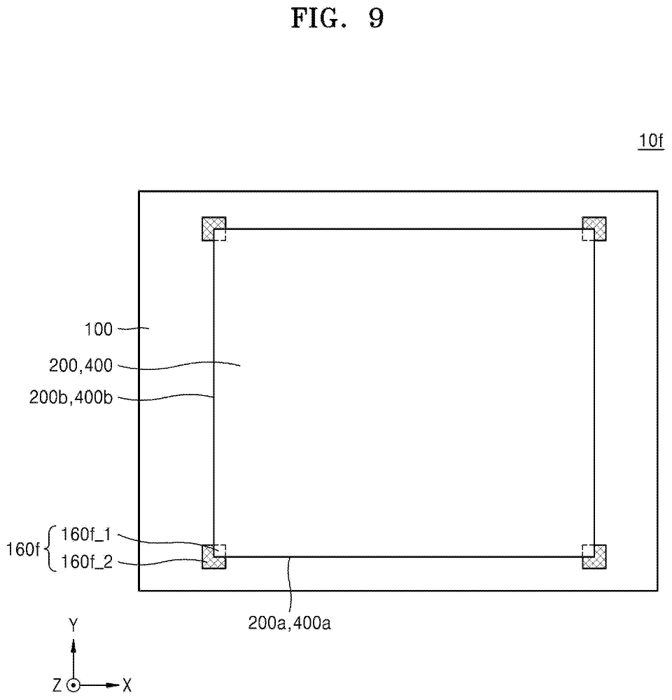

FIG. 9 is a plan view of a semiconductor package 10f according to an embodiment. A semiconductor package 10f shown in FIG. 9 is substantially similar to the semiconductor package 10a shown in FIG. 1 except that the shape and the number of stress reduction members 160f differs from those of the semiconductor package 10a.

Referring to FIG. 9, in an embodiment, a plurality of stress reduction members 160f are provided, and, when viewed from above, the vertices of the plurality of second semiconductor chips 200 and the vertices of the support dummy substrate 400 overlap the centers of the plurality of stress reduction members 160f that respectively correspond thereto. In FIG. 9, the plurality of second semiconductor chips 200 and the support dummy substrate 400 each has a rectangular shape with four vertices, and thus there are four stress reduction members 160f that correspond thereto. However, the number of the stress reduction members 160f is not necessarily limited thereto, and the number of corresponding stress reduction members 160f varies depending on the shapes of the plurality of second semiconductor chips 200 and the support dummy substrate 400.

A stress reduction member 160f includes a first portion 160f_1 that overlaps the plurality of second semiconductor chips 200 and/or the support dummy substrate 400 in the vertical direction (Z direction), and a second portion 160f_2 that does not overlap the plurality of second semiconductor chips 200 or the support dummy substrate 400 in the vertical direction (Z direction). The area of the top surface of the second portion 160f_2 is greater than the area of the top surface of the first portion 160f_1. For example, when a vertex of the plurality of second semiconductor chips 200 or a vertex of the support dummy substrate 400 is located at the center of the stress reduction member 160f when viewed from above, the area of the top surface of the second portion 160f_2 is 3 times the area of the top surface of the first portion 160f_1.

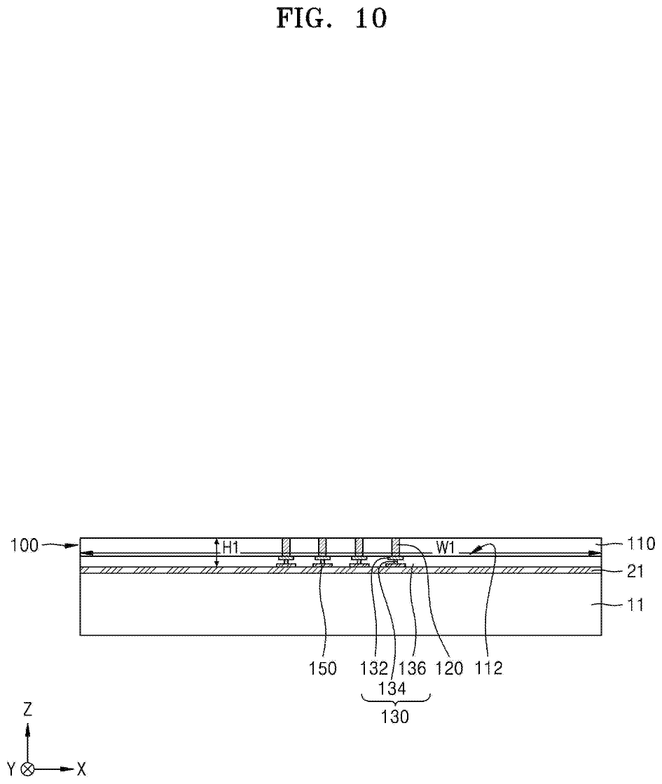

FIGS. 10 to 21 are cross-sectional views that illustrate a method of manufacturing a semiconductor package according to an embodiment. For example, FIGS. 10 to 21 are cross-sectional views that illustrate a method of manufacturing the semiconductor package 10a shown in FIGS. 1 to 3, and descriptions identical to those given above with reference to FIGS. 1 to 3 may be omitted.

Referring to FIG. 10, in an embodiment, the first semiconductor chip 100 is attached onto a first support substrate 11. The first semiconductor chip 100 is attached onto a first release film 21 after the first release film 21 is attached onto the top surface of the first support substrate 11. The first semiconductor chip 100 is attached onto the first release film 21, such that the first wiring structure 130 faces the first support substrate 11. The plurality of chip pads 150 exposed on the bottom surface of the first semiconductor substrate 110 are attached to the first release film 21.

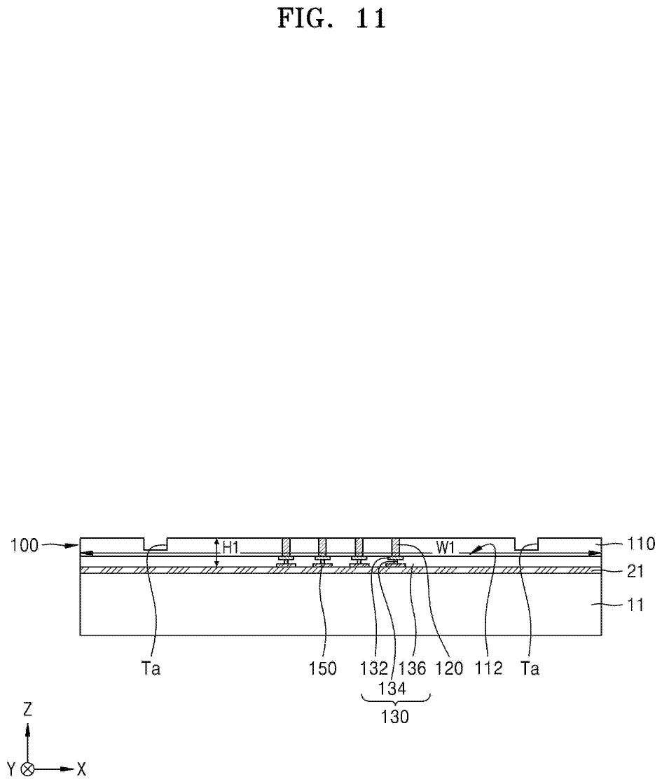

Referring to FIG. 11, in an embodiment, the trench Ta is formed in the top surface, such as an inactive surface, of the first semiconductor substrate 110. The trench Ta is formed to extend from the top surface of the first semiconductor substrate 110 toward the bottom surface, such as an active surface. The trench Ta can be formed through an etching process.

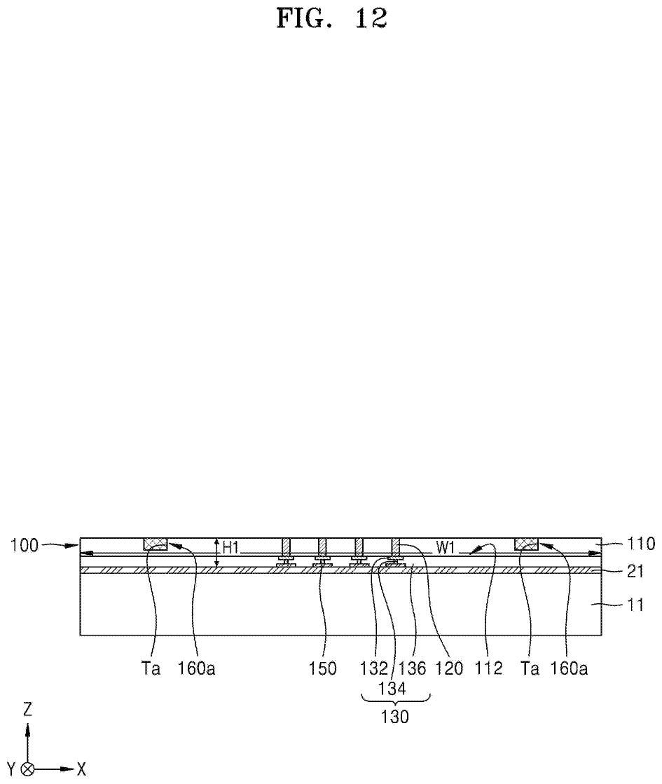

Referring to FIG. 12, in an embodiment, the stress reduction member 160a is formed to fill the trench Ta in the top surface of the first semiconductor substrate 110. To form the stress reduction member 160a, a material that includes at least one of a filler, an epoxy molding compound, a polymer, or a combination thereof, is deposited in the trench Ta. As shown in FIG. 1, the stress reduction member 160a is formed on the top surface of the first semiconductor substrate 110 and has a rectangular ring-like shape.

Referring to FIG. 13, in an embodiment, a plurality of first chip connection pads 322 and a first chip bonding insulation material layer 302 are formed on the top surface of the first semiconductor chip 100. The plurality of first chip connection pads 322 are arranged on the top surface, such as the inactive surface, of the first semiconductor chip 100. The plurality of first chip connection pads 322 are connected to the plurality of first through silicon vias 120. The first chip bonding insulation material layer 302 is formed to surround side surfaces of the plurality of first chip connection pads 322 on the top surface of the first semiconductor chip 100. The first chip bonding insulation material layer 302 covers the top surface of the first semiconductor chip 100 and the side surfaces of the plurality of first chip connection pads 322, but exposes top surfaces of the plurality of first chip connection pads 322 without covering them. The first chip bonding insulation material layer 302 is formed to completely cover the top surface of the stress reduction member 160a.

The plurality of first chip connection pads 322 and the first chip bonding insulation material layer 302 are also formed on the top surface of the second semiconductor chip 200. The plurality of first chip connection pads 322 are arranged on the top surface, such as the inactive surface, of the second semiconductor chip 200. The plurality of first chip connection pads 322 are connected to the plurality of second through silicon vias 220. The first chip bonding insulation material layer 302 surrounds side surfaces of the plurality of first chip connection pads 322 on the top surface of the second semiconductor chip 200. The first chip bonding insulation material layer 302 covers the top surface of the second semiconductor chip 200 and the side surfaces of the plurality of first chip connection pads 322, but expose top surfaces of the plurality of first chip connection pads 322 without covering them.

A plurality of second chip connection pads 324 and a second chip bonding insulation material layer 304 are formed on the bottom surface of the second semiconductor chip 200. The plurality of second chip connection pads 324 are arranged on the bottom surface of the second semiconductor chip 200, such as the bottom surface of the second wiring structure 230. The plurality of second chip connection pads 324 are connected to the second wiring patterns 232 and/or the second wiring vias 234. The second chip bonding insulation material layer 304 is formed to surround side surfaces of the plurality of second chip connection pads 324 on the bottom surface of the second semiconductor chip 200. The second chip bonding insulation material layer 304 covers the bottom surface of the second semiconductor chip 200 and the side surfaces of the plurality of second chip connection pads 324, but exposes bottom surfaces of the plurality of second chip connection pads 324 without covering them.

The second semiconductor chip 200 is placed on the first semiconductor chip 100. The second semiconductor chip 200 is the lowermost second semiconductor chip 200L shown in FIG. 2. The lowermost second semiconductor chip 200L is placed on the first semiconductor chip 100, such that the second wiring structure 230 faces the first semiconductor chip 100. The lowermost second semiconductor chip 200L is placed on the first semiconductor chip 100, such that the plurality of second chip connection pads 324 formed on the bottom surface of the lowermost second semiconductor chip 200L correspond to the plurality of first chip connection pads 322 formed on the top surface of the first semiconductor chip 100, respectively.

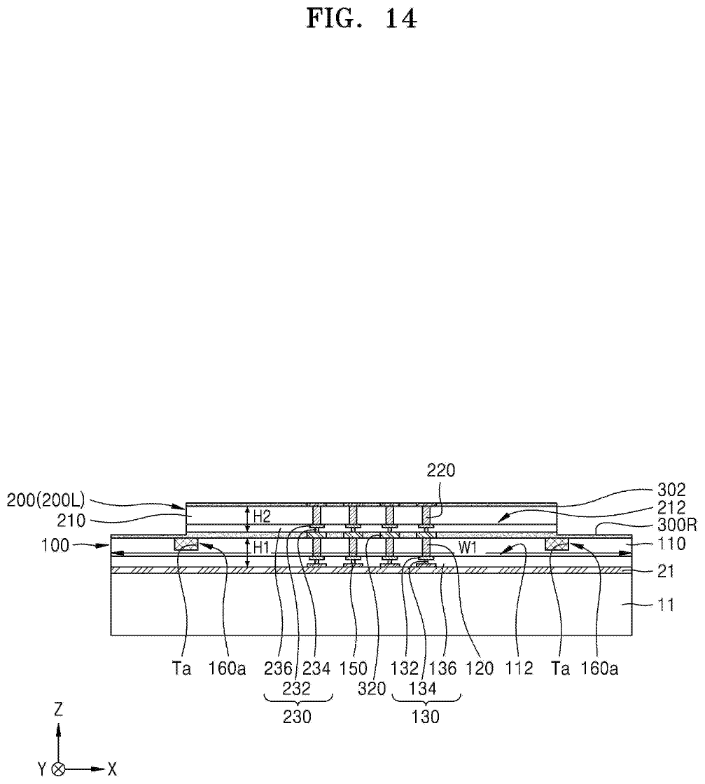

Referring to FIGS. 13 and 14, in an embodiment, in the process of placing the lowermost second semiconductor chip 200L on the first semiconductor chip 100, heat and/or pressure is applied to bond the plurality of first chip connection pads 322 and the plurality of second chip connection pads 324 to each other and bond the first chip bonding insulation material layer 302 and the second chip bonding insulation material layer 304 to each other. According to some embodiments, covalent bonds are formed between the plurality of first chip connection pads 322 and the plurality of second chip connection pads 324 and between the first chip bonding insulation material layer 302 and the second chip bonding insulation material layer 304. For example, heat of a first temperature is applied in the process of placing the second semiconductor chip 200 on the first semiconductor chip 100.

Heat at a second temperature higher than the first temperature is applied to form the plurality of bonding pads 320 in which the plurality of first chip connection pads 322 and the plurality of second chip connection pads 324 are bonded to each other and the chip bonding insulation layer 300 in which the first chip bonding insulation material layer 302 and the second chip bonding insulation material layer 304 are bonded to each other. The plurality of first chip connection pads 322 and the plurality of second chip connection pads 324 that correspond to each other contact each other through thermal expansion and are diffusion-bonded to be integrated with each other through diffusion of metal atoms therein, thereby forming the plurality of bonding pads 320.

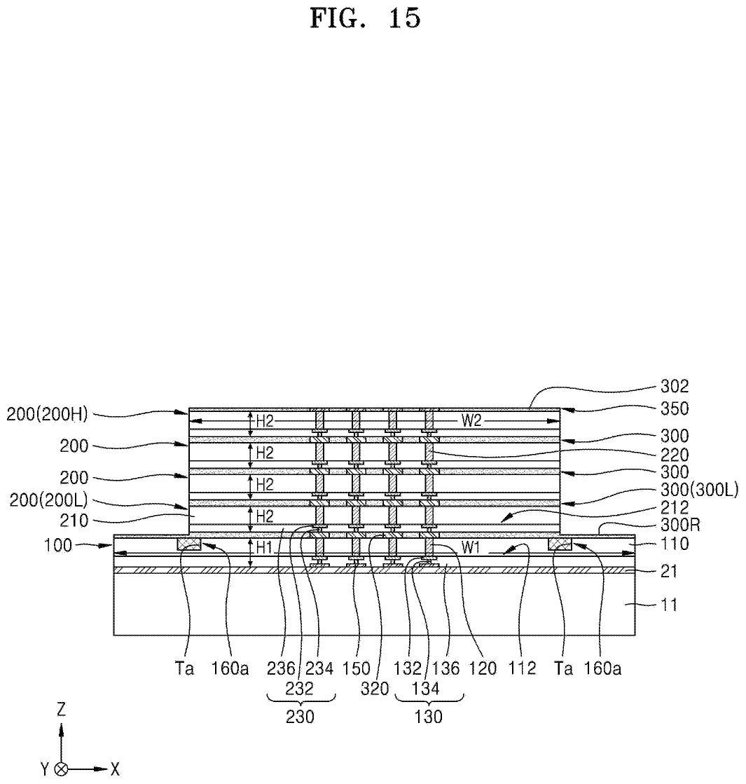

Referring to FIG. 15, in an embodiment, the plurality of second semiconductor chips 200 are sequentially placed on the lowermost second semiconductor chip 200L. The plurality of second chip connection pads 324 and the second chip bonding insulation material layer 304 are formed on the bottom surface of each of the plurality of second semiconductor chips 200 sequentially placed on the lowermost second semiconductor chip 200L, and the plurality of first chip connection pads 322 and the first chip bonding insulation material layer 302 are formed on the top surface of each of the plurality of second semiconductor chips 200 other than the uppermost second semiconductor chip 200H. A first support bonding insulation material layer 360 is formed on the top surface of the uppermost second semiconductor chip 200H.

Thereafter, in a manner similar to that described above with reference to FIG. 14, the plurality of bonding pads 320 are formed by bonding the plurality of first chip connection pads 322 and the plurality of second chip connection pads 324 that correspond to each other to each other, and the chip bonding insulation layer 300 is formed by bonding the first chip bonding insulation material layer 302 and the second chip bonding insulation material layer 304 to each other, thereby sequentially attaching the plurality of second semiconductor chips 200 onto the first semiconductor chip 100.

Referring to FIG. 16, in an embodiment, after forming a second support bonding insulation material layer 370 on the bottom surface of the support dummy substrate 400, the support dummy substrate 400 is placed on the uppermost second semiconductor chip 200H.

The plurality of second semiconductor chips 200 each have the second horizontal width W2, and the support dummy substrate 400 has the third horizontal width W3 that is less than the second horizontal width W2. According to some embodiments, the third horizontal width W3 is less than the second horizontal width W2 by several micrometers to hundreds of micrometers.

The support dummy substrate 400 is placed on the uppermost second semiconductor chip 200H by using edges of the uppermost second semiconductor chip 200H as an alignment key.

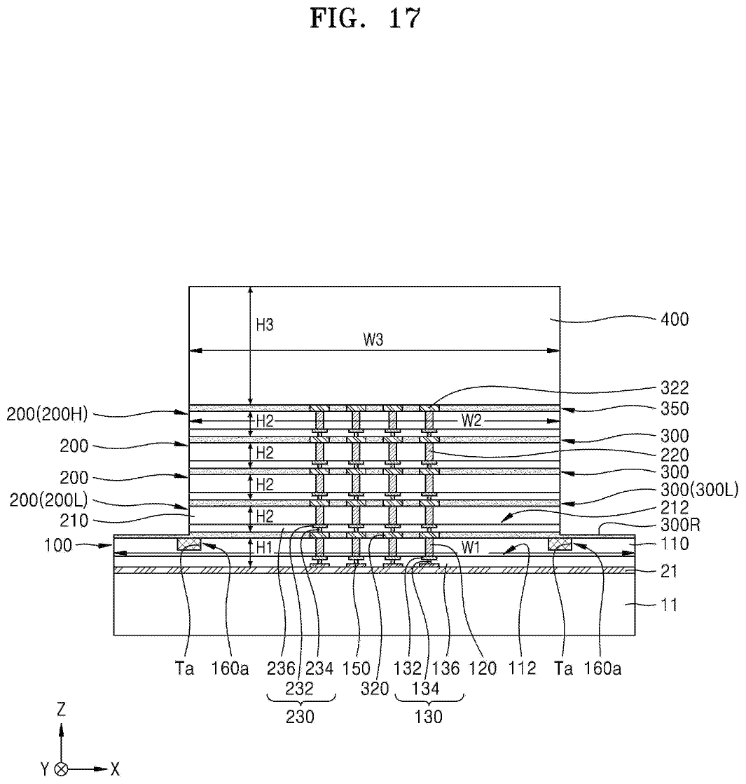

Referring to FIG. 17, in an embodiment, the support bonding insulation layer 350 between the uppermost second semiconductor chip 200H and the support dummy substrate 400 is formed by bonding the first support bonding insulation material layer 360 and the second support bonding insulation material layer 370 to each other, thereby attaching the support dummy substrate 400 onto the uppermost second semiconductor chip 200H.

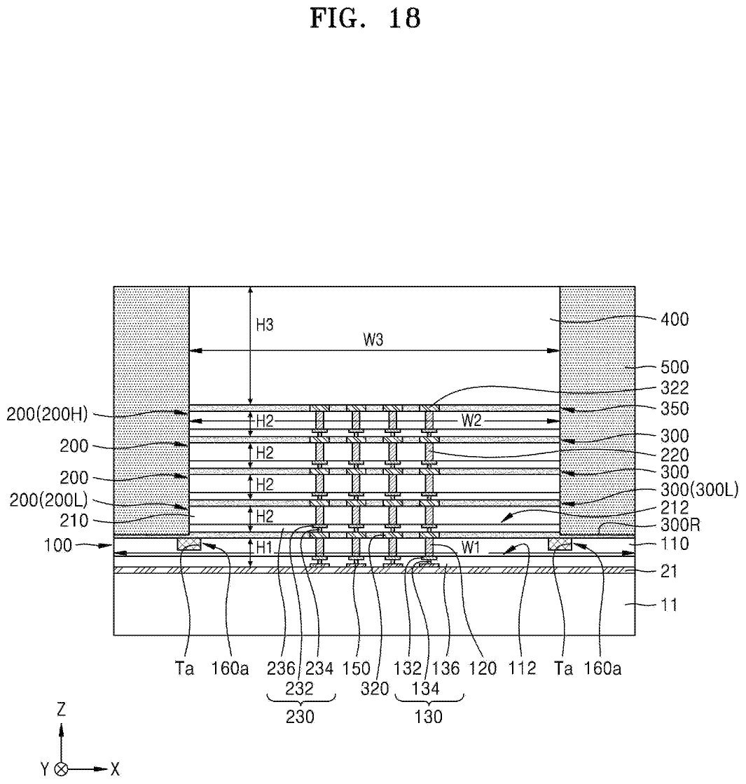

Referring to FIG. 18, in an embodiment, the package molding layer 500, which covers the top surface of the first semiconductor chip 100 and surrounds side surfaces of the plurality of second semiconductor chips 200 and the support dummy substrate 400, is formed on the first semiconductor chip 100.

After forming the package molding layer 500, the first support substrate 11 to which the first release film 20 is attached is separated from the first semiconductor chip 100.

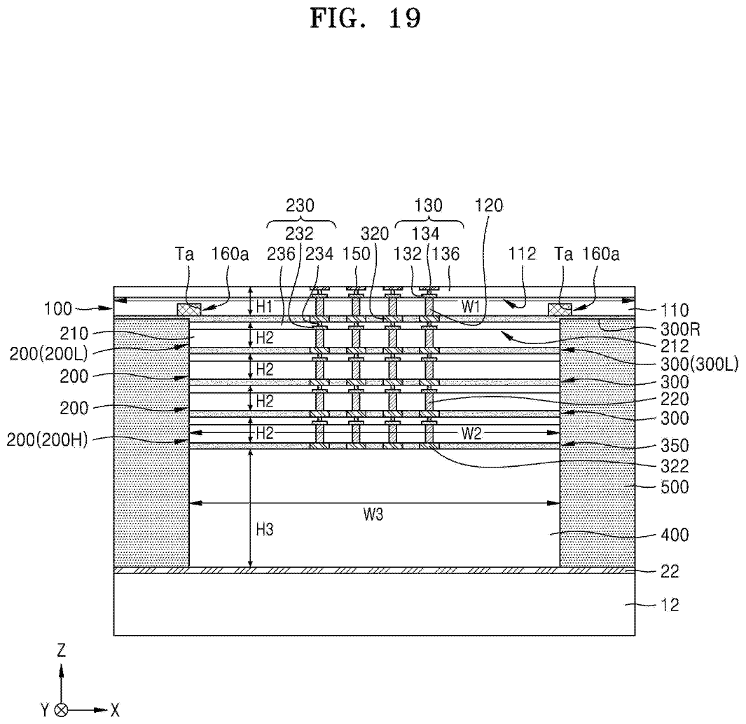

Referring to FIG. 19, in an embodiment, a result structure of FIG. 18 is turned over and attached to a second support substrate 12. The result structure of FIG. 19 is attached onto a second release film 22 after the second release film 22 is attached to the top surface of the second support substrate 12. The support dummy substrate 400 and the package molding layer 500 may be contact the second release film 22.

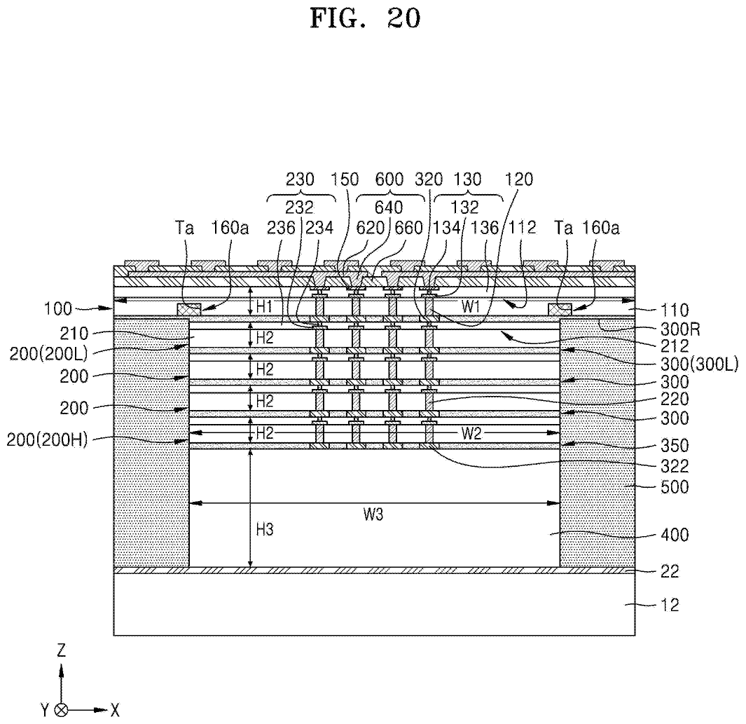

Referring to FIG. 20, in an embodiment, the base redistribution layer 600 is formed on the first wiring structure 130 of the first semiconductor chip 100. The base redistribution layer 600 includes the plurality of package redistribution line patterns 620, the plurality of package redistribution vias 640, and the package redistribution insulation layer 660. At least some of the plurality of package redistribution vias 640 or at least some of the plurality of package redistribution line patterns 620 are formed to contact the plurality of chip pads 150. Of the plurality of package redistribution line patterns 620, the package redistribution line pattern 620 disposed on the top surface of the base redistribution layer 600 may be referred to as a package pad 650.

According to some embodiments, the plurality of package redistribution vias 640 are formed to have a tapered shape in which the horizontal width thereof increases upward in the vertical direction. For example, the plurality of package redistribution vias 640 are formed to have the horizontal width that increases in a direction away from the first semiconductor chip 100.

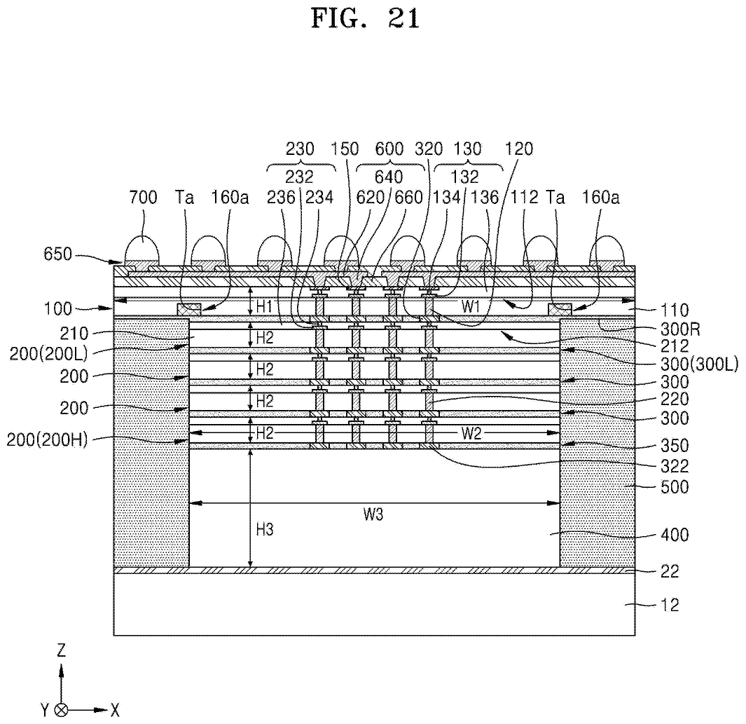

Referring to FIG. 21, in an embodiment, the plurality of package connection terminals 700 are attached to the plurality of package pads 650.

Thereafter, after the second support substrate 12 to which the second release film 22 is attached is separated from the support dummy substrate 400 and the package molding layer 500, a result structure thereof is turned over to form the semiconductor package 10a shown in FIGS. 1 to 3.

While embodiments of the inventive concept have been particularly shown and described with reference to drawings thereof, it will be understood that various changes in form and details may be made therein without departing from the spirit and scope of the following claims.

What is claimed is:

1. A semiconductor package, comprising:
a first semiconductor chip that includes a first semiconductor substrate that includes an active surface and an inactive surface opposite to each other and a plurality of first through silicon vias (TSV) that penetrate through the first semiconductor substrate;
a plurality of second semiconductor chips that each include a second semiconductor substrate that includes an active surface and an inactive surface opposite to each other and a plurality of second through silicon vias that penetrate through the second semiconductor substrate, wherein each of the plurality of second semiconductor chips is stacked on the first semiconductor chip such that the active surface of each second semiconductor substrate faces the inactive surface of the first semiconductor substrate, and the plurality of second semiconductor chips have a same vertical height;
a plurality of bonding pads interposed between the first semiconductor chip and the plurality of second semiconductor chips and that electrically interconnect the plurality of first through silicon vias and the plurality of second through silicon vias; and
a chip bonding insulation layer that surrounds the plurality of bonding pads and is interposed between the first semiconductor chip and the plurality of second semiconductor chips,
wherein the first semiconductor substrate includes a stress reduction member that fills a trench formed in the inactive surface and that extends toward the active surface and overlaps the plurality of second semiconductor chips in a vertical direction perpendicular to the inactive surface.

2. The semiconductor package of claim 1, wherein a height of the stress reduction member in the vertical direction is less than or equal to half a height of the first semiconductor substrate in the vertical direction.

3. The semiconductor package of claim 1, wherein
the stress reduction member comprises at least one of a filler, an epoxy molding compound, a polymer, or a combination thereof,
the filler includes at least one of silicon oxide (SiO), titanium oxide (TiO), aluminum oxide (AlO), silicon carbide (SiC), boron nitride (BN), or a combination thereof, and
the polymer includes a thermoplastic resin.

4. The semiconductor package of claim 1, further comprising
a package molding layer that covers a top surface of the first semiconductor chip and surrounds side surfaces of the plurality of second semiconductor chips,
wherein the stress reduction member comprises:
a first portion that overlaps the plurality of second semiconductor chips in the vertical direction; and
a second portion that overlaps the package molding layer in the vertical direction.

5. The semiconductor package of claim 4, wherein a width of the first portion in a horizontal direction is greater than a width of the second portion in the horizontal direction.

6. The semiconductor package of claim 1, wherein
each of the plurality of second semiconductor chips includes first edges that extend in a first horizontal direction and second edges that extend in a second horizontal direction perpendicular to the first horizontal direction, and
the stress reduction member overlaps the second edges in the vertical direction and does not overlap the first edges in the vertical direction.

7. The semiconductor package of claim 6, wherein the stress reduction member comprises:
a first portion that overlaps the plurality of second semiconductor chips in the vertical direction; and
a second portion that does not overlap the plurality of second semiconductor chips in the vertical direction, and
the second portion protrudes from the first edges in the second horizontal direction.

8. The semiconductor package of claim 1, wherein
the stress reduction member comprises a plurality of stress reduction members, and,
when viewed from above, vertices of the plurality of second semiconductor chips overlap centers of respectively corresponding stress reduction members of the plurality of stress reduction members.

9. The semiconductor package of claim 8, wherein
each of the plurality of stress reduction members includes a first portion that overlaps the plurality of second semiconductor chips in the vertical direction and a second portion that does not overlap the second semiconductor chips, and
an area of a top surface of the second portion is greater than an area of a top surface of the first portion.

10. The semiconductor package of claim 1, wherein the stress reduction member has a tapered shape in which a width thereof in a horizontal direction decreases in a direction toward the inactive surface of the first semiconductor substrate.

11. A semiconductor package, comprising:
a high-bandwidth memory (HBM) control die that includes a first semiconductor substrate that includes an active surface and an inactive surface opposite to each other and a plurality of first through silicon vias that penetrate through at least a portion of the first semiconductor substrate;
a plurality of dynamic random access memory (DRAM) dies that each include a second semiconductor substrate that includes an active surface and an inactive surface opposite to each other and a plurality of second through silicon vias that penetrate through the second semiconductor substrate, wherein each of the plurality of DRAM dies is stacked on the HBM control die such that the active surface of each second semiconductor substrate faces the inactive surface of the first semiconductor substrate, and the plurality of DRAM dies have the same vertical height;
a plurality of bonding pads interposed between the HBM control die and the plurality of DRAM dies and that electrically interconnects the plurality of first through silicon vias and the plurality of second through silicon vias;
a chip bonding insulation layer that surrounds the plurality of bonding pads and is interposed between the HBM control die and the plurality of DRAM dies; and
a package molding layer that covers a top surface of the HBM control die and surrounds side surfaces of the plurality of DRAM dies,
wherein the HBM control die includes a stress reduction member that fills a trench formed in the inactive surface and extends toward the active surface of the first semiconductor substrate and overlaps the plurality of DRAM dies in a vertical direction perpendicular to the inactive surface of the first semiconductor substrate,
wherein the stress reduction member includes a first portion that overlaps the plurality of DRAM dies in the vertical direction and has a first width in the horizontal direction, and a second portion that overlaps the package molding layer in the vertical direction and has a second width in the horizontal direction, wherein the second width is greater than or equal to the first width.

12. The semiconductor package of claim 11, further comprising
a support dummy substrate stacked on the plurality of DRAM dies,
wherein a height of the support dummy substrate in the vertical direction is greater than a height of each of the plurality of DRAM dies in the vertical direction.

13. The semiconductor package of claim 12, wherein a height of the support dummy substrate in the vertical direction is less than a sum of heights of the plurality of DRAM dies and a height of the first semiconductor substrate in the vertical direction.

14. The semiconductor package of claim 11, wherein
a height of the stress reduction member in the vertical direction is within a range from about 20 micrometers to about 35 micrometers, and
a sum of the first width and the second width of the stress reduction member is within a range from about 0.7 millimeters to about 1.3 millimeters.

15. The semiconductor package of claim 11, wherein a height of the stress reduction member in the vertical direction is less than or equal to half a height of the first semiconductor substrate in the vertical direction.

16. The semiconductor package of claim 11, wherein
the stress reduction member includes a plurality of stress reduction members,
each of the plurality of stress reduction members has a rectangular shape when viewed from above, and
vertices of each of the plurality of DRAM dies overlaps centers of corresponding stress reduction members of the plurality of stress reduction members when viewed from above.

17. The semiconductor package of claim 11, wherein
side surfaces of the plurality of DRAM dies are aligned on a same plane, and
the side surfaces of the plurality of DRAM dies each overlap the stress reduction member when viewed from above.

18. A semiconductor package, comprising:
a base redistribution layer that includes a plurality of package redistribution line patterns, a plurality of package redistribution vias that contact and are connected to at least some of the plurality of package redistribution line patterns, and a package redistribution insulation layer that surrounds the plurality of package redistribution line patterns and the plurality of package redistribution vias;
a high-bandwidth memory (HBM) control die that includes a first semiconductor substrate that includes a first active surface and a first inactive surface opposite to each other and a plurality of first through silicon vias that penetrate through the first semiconductor substrate, wherein the HBM control die is disposed on the base redistribution layer such that the first inactive surface faces the base redistribution layer;
a plurality of dynamic random access memory (DRAM) dies that each include a second semiconductor substrate that includes a second active surface and a second inactive surface opposite to each other and a plurality of second through silicon vias that penetrate through the second semiconductor substrate, wherein each of the plurality of DRAM dies is stacked on the HBM control die such that each second active surface faces the first inactive surface, and the plurality of DRAM dies have the same vertical height and a horizontal width identical to a horizontal width of the HBM control die;
a plurality of bonding pads interposed between the HBM control die and the plurality of DRAM dies and that electrically interconnect the plurality of first through silicon vias and the plurality of second through silicon vias;
a chip bonding insulation layer that surrounds the plurality of bonding pads and that are interposed between the HBM control die and the plurality of DRAM dies;
a support dummy substrate stacked on the plurality of DRAM dies; and
a package molding layer disposed on the HBM control die and that covers a top surface of the HBM control die and side surfaces of the plurality of DRAM dies, and exposes a top surface of the support dummy substrate without covering the top surface of the support dummy substrate,
wherein the HBM control die includes a stress reduction member that fills a trench formed in the first inactive surface and that extends toward the first active surface and overlaps the plurality of DRAM dies in a vertical direction perpendicular to the inactive surface, and
the stress reduction member includes a first portion that overlaps the plurality of DRAM dies in the vertical direction and has a first width in the horizontal direction and a second portion that overlaps the package molding layer in the vertical direction and has a second width in the horizontal direction, wherein the second width is greater than or equal to the first width.

19. The semiconductor package of claim 18, wherein
a height of the first semiconductor substrate in a vertical direction is within a range from about 50 micrometers to about 70 micrometers,
a height of the stress reduction member in the vertical direction is within a range from about 20 micrometers to about 35 micrometers, and
a sum of the first width and the second width of the stress reduction member is within a range from about 0.7 millimeters to about 1.3 millimeters.

20. The semiconductor package of claim 18, wherein
the stress reduction member includes at least one of a filler, an epoxy molding compound, a polymer, or a combination thereof,
the filler includes at least one of silicon oxide (SiO), titanium oxide (TiO), aluminum oxide (AlO), silicon carbide (SiC), boron nitride (BN), or a combination thereof, and
the polymer includes a thermoplastic resin.
